(19) United States
(12) Patent Application Publication
(10) Pub. No.: US 2010/0102823 A1
(43) Pub. Date: Apr. 29, 2010

(54) ERROR RECOGNITION IN A CONTROL UNIT

(76) Inventors: Norbert Knab, Appenweier (DE); Georg Schulze-Icking-Konert, Buehlertal (DE); Thomas Mohr, Buehlertal (DE); Stefan Kotthaus, Sinzheim (DE); Nikolas Haberl, Sinzheim (DE); Michael Mueller, Rutesheim (DE)

Correspondence Address: MERCHANT & GOULD PC, P.O. BOX 2903, MINNEAPOLIS, MN, 55402-0903, US

(21) Appl. No.: 12/593,055

(22) PCT Filed: Jan. 28, 2008
(86) PCT No.: PCT/EP08/50931

§ 371 Date: Sep. 25, 2009

(30) Foreign Application Priority Data
Mar. 26, 2007 (DE) 10-2007-014-335.6

(51) Int. Cl. G01R 31/00

(52) U.S. Cl. 324/500

(57) ABSTRACT

The invention relates to an error recognition device for detecting an error in an electrical component (1), comprising a first detector (12), a second detector (13) for detecting a parameter characteristic of current flows, and a triggering unit (10) for interrupting a current flow through the electrical component (1) by means of a switch (S2), depending on the parameter characteristic of the detected current flows.

The invention relates to an error recognition in an electrical component with a control unit and a consumer, whereby an error in the control unit as well as in the consumer can be detected.

In order to protect electrical systems against overheating fuses are usually used, which interrupt the current flow in a current conducting conductor, if a short occurs or an improperly high current flows and/or the ambient temperature of the corresponding component exceeds a threshold temperature. Furthermore error cases can occur, at which a leakage current or any other kind of current flows in a control unit of the electrical component, which does not flow through the consumer that is connected to the control unit. Such error currents within the control unit can possibly not cause a triggering of the fuse, but can overheat the control unit or cause different damages in the control unit, in the electrical component or in the end application, which is built into the electrical component.

Therefore it is necessary also to detect errors in the electrical component, which do not cause an obligatory current flow in the feed lines, which for example lies above the maximally allowed current and therefore would cause an instant triggering of the fuse.

An overheating of the component can already take place below the maximum operating current, if a thermal output is set free in the control unit. But it would be detected by a fuse only delayed, in particular if it is arranged outside of the control unit. To avoid damages it is useful to detect a possible error faster.

It is therefore the task of the present invention to provide an error recognition device for a reliable detection of error cases in an electrical component, at which an overheating can occur, even if the supplied current does not exceed the allowed maximum current.

Furthermore error cases should be detected by the device, before an overheating in particular of the control unit can occur. Additionally error cases should also be detected, which cause high currents, but no overheating in the component, as for example a hard short in the control unit or the consumer.

### DISCLOSURE OF THE INVENTION

This task is solved by the error recognition device for detecting error in an electrical component according to claim 1, an electrical system with such an error recognition device, a control unit and a consumer according to claim 5 as well as an application of an error recognition device in an electrical component according to claim 8.

Further advantageous embodiments of the invention are stated in the dependant claims.

According to a first aspect an error recognition device is provided for detecting an error in an electrical component. The error recognition device comprises a first detector and a second detector for detecting a parameter characteristic of current flows as well as a triggering unit for interrupting a current flow through the electrical component by means of a switch, depending on the parameter characteristic of the detected current flows.

The error recognition device is particularly useful for the controlling components with a control unit and a consumer, whereby the consumer is controlled by the control unit, for example over the power or according to a switch-on or off procedure and similar errors.

Furthermore the triggering unit can comprise a comparator for comparing the parameter characteristics of the detected current flows with each other and interrupting the current flow through the electrical component depending on a difference of the detected current flows, and can furthermore comprise an integrator for integrating the result of the comparator, so that the switch is controlled with a low pass filtered control parameter.

According to an embodiment the first and/or second detector can provide a shunt, through which the current flow that has to be measured is supplied, in order to provide a measuring voltage that depends on the current flow, whereby the each measuring voltage is provided to the triggering unit.

Furthermore the first and/or second detector can be arranged in the triggering unit.

According to a further aspect an electrical component with a consumer, a control unit for controlling the consumer and the above error recognition device can be provided. The first detector is arranged on a first current path from the control unit to the consumer in front of the control unit and the second detector is arranged in a second current path from the consumer to the control unit between the consumer and the control unit.

At least one of the elements, the first the detector, the second detector and the triggering unit, can be provide in the control unit to enable an integrated construction.

The control unit can furthermore be connected by a first access line with a first direct current voltage potential and by a second access line with a second direct current voltage potential. The consumer is connected with the control unit by a first access line and a second access line, whereby a control module is provided, in order to apply an electrical power at the consumer. The first access line and first connecting line are directly connected with each other over the control unit, whereby the first detector is arranged in the second access line and the second detector in the first connecting line.

According to a further aspect an application of the above error recognition device is provided in an electrical component. It comprises a consumer and a control unit for controlling the consumer, whereby the first detector is arranged on a first current path from the control unit to the consumer in front of the control unit, whereby the second detector is arranged in a second current path from the consumer to the control unit between the consumer and the control unit.

### DRAWINGS

Preferred embodiments of the invention are further explained in the attached drawings. It is shown in:

FIG. 1 a schematic illustration of an electrical system with an error recognition device for detecting an error in an electrical component according to a first embodiment of the invention

FIG. 2 a schematic illustration of an electrical system with an error recognition device for detecting an error in an electrical component according to a further embodiment of the invention and

FIG. 3 a schematic illustration of an electrical system with an error recognition device for detecting an error in an electrical component according to a first embodiment of the invention.

The same reference signs label elements with the same or comparable function in the figures.

### EMBODIMENTS OF THE INVENTION

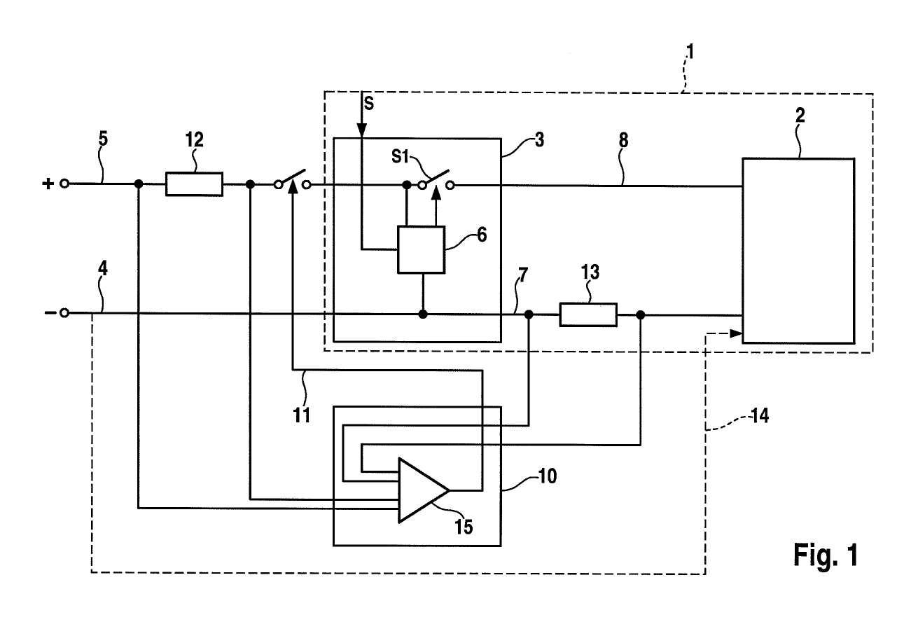

FIG. 1 shows an electrical component 1 with a consumer 2, for example a fan motor and a control unit 3, which is supplied with electrical energy, for example an electrical direct current, by a first 4 and a second access line 5. The control unit 3 controls the consumer 2 according to a provided manipulated variable S in order to provide the consumer 2 depending on the manipulated variable S with a certain electrical power. The control unit 3 can for example produce a pulse width modulated signal with the aid of a control module 6 depending on the manipulated variable S, with which a first switch S1 is controlled, which means opened or closed. The manipulated variable S controls thereby the duty cycle between the on-state and an off-state of the switch S1 in the control unit 3, which means that depending on S the duration during which the switch S1 is closed and the time duration during which the switch S1 is opened is determined during a predefined cycle time. The first switch S1 in the control unit 3 is preferably construed as power transistor. Alternatively the control unit can control the consumer in a different way, for example depending on the manipulated variable S, for example switching on and off according to a predefined function.

The control unit 3 is connected to the consumer 2 by a first connecting line 7 and a second connecting line 8 in order to supply the electrical energy. In the shown embodiment the first access line 4 is thereby directly connected with the first connecting line 7 over the control unit 3 and the second access line 5 with the second connecting line 8 over the first switch S1. It is obviously also possible to arrange the switch S1 in the connection between the first access line 4 and the first connecting line 7.

In order to detect errors due to erroneous current flows in the component 1 a triggering unit 10 is furthermore provided, which interrupts a current flow through the component by a second switch S2 depending on the detection of an error. The second switch S2 is connected in one of the access lines, for example in the second access line as it is shown in FIG. 1. The second switch S2 is controlled by the triggering unit 10 with a control signal through a control line 11, in order to open the second switch S2 in the case of a triggering. Thereby the supply of electrical energy into the control unit 3 and the consumer 2 is interrupted in the case of an error. In the normal case, which means if no error occurs, the second switch S2 is closed.

With the aid of a first detector 12, which is arranged in the second supply line 5 and a second detector 13, which is arranged in the first connecting line 7 between the control unit 3 and the consumer 2, the currents on each line are detected and evaluated in the triggering unit 10. The first detector 12 and the second detector 13 are arranged in such a way that the current paths of the consumer 2, which means for example of the engine, and of the control unit 3 are arranged between them, so that in the normal case a current outlet on the current path between the two detectors 12, 13 causes a detection of a current difference in the triggering unit 10. The detection of the current difference is carried out by a comparator 15 in the triggering unit 10, at whose outlet the control signal for the second switch S2 is applied. The triggering unit 10 controls then in the case of an error, which is defined by the detection of a current difference, the second switch S2, in order to open it.

Thus it can be detected, if an outlet of the current from the current path between the first detector 12 and to the second detector 12, which mean current flows off in the consumer 2 or from the control unit 3 to a further potential, for example a mass potential, does not take place over the corresponding access line or connecting line. A direct current voltage could for example be applied in a motor vehicle over the access lines and also other conducting areas (housing and such alike) could be provided in the consumer 2 besides the connecting line with the negative (more negative) potential, which are applied on the negative potential. This is indicated by the dotted mass line 15 between the first access line 4 and the consumer 2. If current flows off over the second connecting line (positive (more positive) potential) over the mass line 14 (which is equal to a mass shunt in the consumer), the current flows through the detectors 12, 13 are not equal and an error is detected.

Because the control unit 3 is integrated in a non-conductive housing depending on the application, electrical or electronic element that are inside of it are usually not floating, which means internal conductors can usually not come into contact with another potential (as for example the negative potential), if it is not supplied over the access lines 4, 5. But it is possible that a further error case is detected for the control unit 3, at which a short or a current bridge causes an error current between the two potentials of the access lines 4, 5. This can be simply determined by the special arrangement of the detectors 12, 13, whereby the first detector 12 is detected in front of the control unit 3 and the second detector 13 behind the control unit 3 with regard to the arrangement of the control unit 3 and the consumer 2.

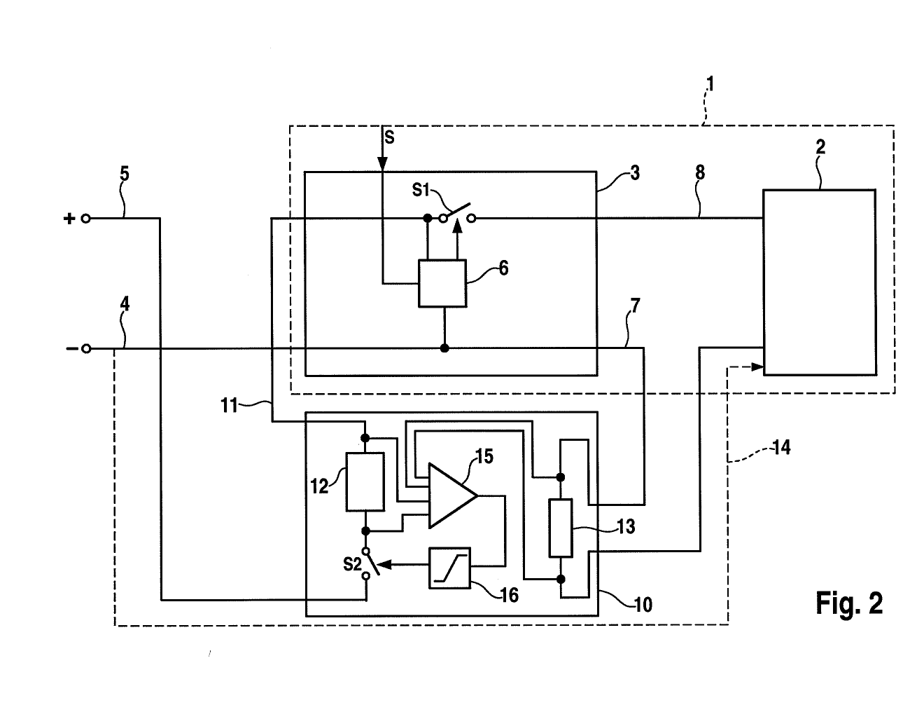

The detectors 12, 13 can be arranged in the corresponding lines and be connected over signal lines with the triggering unit 10. Alternatively the corresponding current conducting lines can be running through the control unit 10, as for example shown in FIG. 2, and there be measured and compared, in order to determine the error case. Furthermore the second switch S2 can also be arranged in the control unit 3 and be correspondingly connected with a comparator 15.

The detectors 12, 13 are for example construed as shunts, which means calibrated measuring resistances, at which are voltage can be measured, which is proportional to the current and which is compared by the comparator 15 with each other, in order to determine an error in the case of a deviation of the voltages. A deviation that is relevant for an error can thereby be detected not until exceeding a difference threshold value by the detected difference. With other words, a tolerance can be considered when comparing the currents, so that a triggering only takes place, if the current difference exceeds a certain amount. When using shunts as measuring resistances this can be a corresponding threshold value for the voltage difference. The provision of a difference threshold value can be useful if a certain current absorption should be considered by the control module, which can be the reason for a current difference that has been determined by the triggering unit 10.

The (relevant) voltage difference that has been detected in the comparator 15 can cause a triggering right away, at which the second switch S2 is opened. Alternatively the voltage difference can also be filtered by a low pass filter 16, which can for example be construed as integrator, so that the triggering takes only place when an integration value of the voltage difference exceeds a certain threshold value over a certain time period.

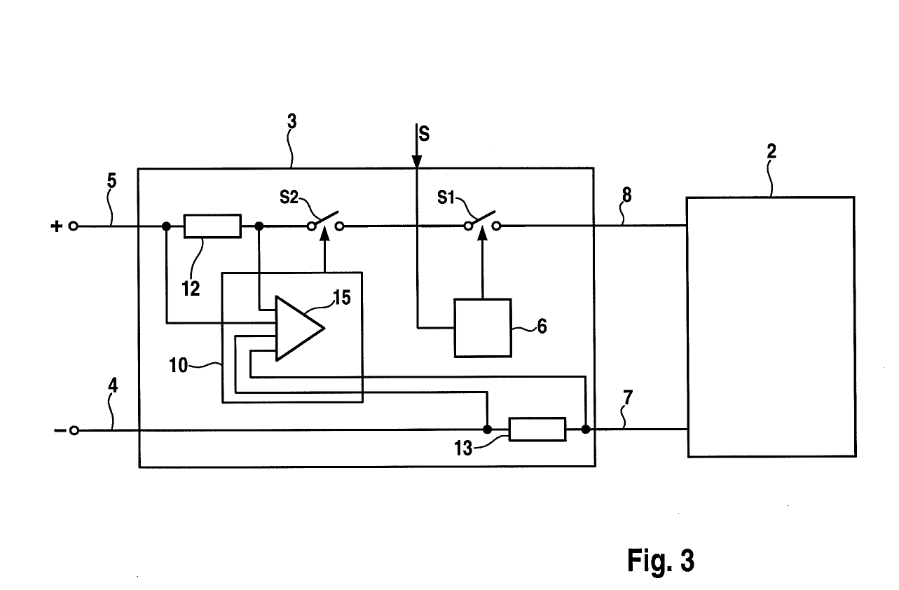

FIG. 3 shows a further embodiment, at which the triggering unit 10 is integrated into the control unit 3. Therefore the detectors 12, 13, the second switch S2 as well as the triggering unit 10 are also provided in the control unit 3. The first detector 12 is arranged directly at the connection, at which the second access line 5 is connected, at which the second access line 5 (or the first access line 4) is connected. The second detector 13 is then directly arranged at the connection of the control unit 3, at which the first connecting line 7 (or the second connecting line 8) is connected.

The control unit 3 can be provided with a sleep-switch (not shown), which puts the control unit in a current safe mode when the entire system is switched-off. A waking up of the control unit 3 can take place by detecting a voltage at the first detector 12.

The circuit according to the invention has the advantage that current outputs in the consumer 2 to further potentials cause a triggering, as well as an internal short in the control unit 3, at which a part of the current does not flow through the consumer 2 but between internal supply lines.

In the above stated embodiments measuring resistances (shunts) are provided as detectors and for determining the current difference the comparator 15 is used, which is particularly useful when providing a direct current as supply current. The detection of the flowing current and the comparing can also be carried out by other measuring procedures. For example a toroidal core coil can be provided when using an alternating current as supply current, whereby the two current conducting lines, at which the current measurement should be carried out, run through the toroidal. A difference current is induced in the toroidal core coil, from which the control signal is determined. Also hall-sensors, GMR-sensors (giant magneto resistance) and such alike can be used as current sensors.

1-8. (canceled)

9. An error recognition device for detecting an error in an electrical component, comprising:
a first detector;
a second detector for detecting a parameter characteristic of current flows; and
a triggering unit for interrupting a current flow through the electrical component with a switch, depending on the parameter characteristic of the detected current flows.

10. The error recognition device of claim 9, wherein the triggering unit comprises:
a comparator configured to compare parameter characteristics of the detected current flows with each other and to interrupt the current flow through the electrical component depending on a difference of the detected current flows; and
an integrator for integrating the result of the comparator so that the switch is controlled with a low pass filtered control parameter.

11. The error recognition device of claim 9, wherein at least one of the first and the second detector comprises a shunt that supplies current to be measured in order to provide a measuring voltage that depends on the current flow, wherein the measuring voltage is provided to the triggering unit.

12. The error recognition device of claim 9, wherein at least one of the first and the second detector are arranged in the triggering unit.

13. The error recognition device of claim 9, further comprising a consumer and a control unit for controlling the consumer, wherein the first detector is arranged on a first current path from the control unit to the consumer in front of the control unit and the second detector is arranged in a second current path from the consumer to the control unit between the consumer and the control unit.

14. An electrical system comprising:
an electrical component with a consumer and a control unit for controlling the consumer; and
an error recognition device for detecting an error in an electrical component, comprising: a first detector; a second detector for detecting a parameter characteristic of current flows; and a triggering unit for interrupting a current flow through the electrical component with a switch, depending on the parameter characteristic of the detected current flows;
wherein the first detector is arranged on a first current path from the control unit to the consumer in front of the control unit and the second detector is arranged in a second current path from the consumer to the control unit between the consumer and the control unit.

15. The electrical system of claim 14, wherein at least one of the first detector, the second detector, and the triggering unit are provided in the control unit.

16. The electrical system of claim 14, further comprising a control module configured to apply electrical power at the consumer, wherein a first access line and a first connecting line are directly connected over the control unit, and wherein the control unit is connected with a first direct current voltage potential over the first access line and with a second direct current voltage potential over a second access line, the first detector is arranged in the second access line and the second detector in the first connecting line, and the consumer is connected with the control unit over the first connecting line and over the second connecting line.
